(19) United States
(12) Patent Application Publication
(10) Pub. No.: US 2024/0290700 A1
(43) Pub. Date: Aug. 29, 2024

(54) BONDING SUBSTRATE, SEMICONDUCTOR PACKAGE HAVING DOUBLE-SIDED SUBSTRATE, METHOD OF MANUFACTURING THE BONDING SUBSTRATE, AND METHOD OF MANUFACTURING THE SEMICONDUCTOR PACKAGE HAVING DOUBLE-SIDED SUBSTRATE

(71) Applicant: JMJ Korea Co., Ltd., Busan (KR)

(72) Inventor: Yun Hwa CHOI, Busan (KR)

(73) Assignee: JMJ Korea Co., Ltd., Busan (KR)

(21) Appl. No.: 18/518,359

(22) Filed: Nov. 22, 2023

(30) Foreign Application Priority Data
Feb. 24, 2023 (KR) 10-2023-0024837

(51) Int. Cl. H01L 23/498; H01L 23/00; H01L 23/14; H01L 23/31; H01L 25/00; H01L 25/065

(52) U.S. Cl. CPC H01L 23/49822; H01L 23/14; H01L 23/3121; H01L 23/49838; H01L 24/29; H01L 24/32; H01L 24/48; H01L 24/73; H01L 25/0655; H01L 25/50; H01L 2224/29111; H01L 2224/29139; H01L 2224/29147; H01L 2224/32225; H01L 2224/48225; H01L 2224/73265; H01L 2924/181

(57) ABSTRACT

Provided is a bonding substrate, a semiconductor package having a double-sided substrate, a method of manufacturing the bonding substrate, and a method of manufacturing the semiconductor package having a double-sided substrate, wherein the bonding substrate includes at least one upper substrate; at least one lower substrate which faces and is spaced apart from the upper substrate by a regular distance; and connecting members which comprises at least two layers formed of each different metal and is structurally or electrically ultrasonic bonded to the upper substrate or the lower substrate by using an ultrasonic bonding device. Accordingly, a tolerance for a vertically separated distance between upper and lower substrates may be minimized through ultrasonic bonding between the substrate and the connecting member and structural stress generated while molding may be reduced by using connecting members having each different Coefficient of Thermal Expansion (CTE).

### CROSS-REFERENCE TO RELATED PATENT APPLICATION

This application claims the benefit of Korean Patent Application No. 10-2023-0024837, filed on Feb. 24, 2023, in the Korean Intellectual Property Office, the disclosure of which is incorporated herein in its entirety by reference.

### BACKGROUND OF THE INVENTION

### 1. Field of the Invention

The present invention relates to a bonding substrate, a semiconductor package having a double-sided substrate, a method of manufacturing the bonding substrate, and a method of manufacturing the semiconductor package having a double-sided substrate, and more particularly, to a bonding substrate, a semiconductor package having a double-sided substrate, and each method of manufacturing the same in which a tolerance for a vertically separated distance between upper and lower substrates may be minimized through ultrasonic bonding between a substrate and a connecting member and structural stress generated while molding may be reduced by using connecting members having each different Coefficient of Thermal Expansion (CTE).

### 2. Description of the Related Art

In general, a semiconductor package includes semiconductor chips installed on a lower substrate and/or an upper substrate, conductors which are metal posts functioning as spacers bonded onto the semiconductor chips, lead frames formed of Cu to apply an electrical signal from the outside, and a package housing molded by a sealing member. Here, the semiconductor chips are bonded onto lead frame pads, and lead frame leads are electrically connected to the pads of the semiconductor chips through bonding wires, which are signal lines, by using a plating layer formed of Ag and interposed therebetween.

For example, as illustrated in a general semiconductor package having a double-sided heat radiation structure of FIG. 1A, semiconductor chips 14 are bonded on a lower metal insulating substrate 11A by using first bonding units 12 interposed therebetween, one sides of hexahedral or cylindrical conductors 17, which are metal spacers each having a vertical structure, are bonded onto the semiconductor chips 14 by using second bonding units 16 interposed therebetween, and other sides of the conductors 17 are bonded onto an upper metal insulating substrate 11B by using third bonding units 13 interposed therebetween.

Here, each of the bonding units 12, 16, and 13 is bonded to the substrates 11A and 11B, the conductors 17, and the semiconductor chips 14 by using solder or Ag or Cu based sinter, however, height adjustment between the lower metal insulating substrate 11A and the upper metal insulating substrate 11B is not easy and thereby, defects such as chip cracks or substrate cracks are generated while molding of a package housing as illustrated in FIG. 1B due to a Coefficient of Thermal Expansion (CTE) difference between the substrates 11A and 11B, the conductors 17, and the first, second, and third bonding units 12, 16, and 13, a thickness tolerance of the bonding units 12, 16, and 13, and a tolerance of each member. Accordingly, a structural reliability of a semiconductor package may be lowered.

Also, in order to minimize a CTE difference with semiconductor chips, metal spacers or metal posts may be replaced with a material similar to a CTE of the semiconductor chips, however, such material is considerably expensive compared with existing metal spacers or metal posts. Accordingly, price competitiveness of products is lowered.

In this regard, there is a demand for technology that may secure structural stability of a semiconductor package by improving a bonding structure between a lower metal insulating substrate or an upper metal insulating substrate and conductors.

### SUMMARY OF THE INVENTION

The present invention provides a bonding substrate, a semiconductor package having a double-sided substrate, and each method of manufacturing the same in which a tolerance for a vertically separated distance between upper and lower substrates may be minimized through ultrasonic bonding between a substrate and a connecting member and structural stress generated while molding may be reduced by using connecting members having each different Coefficient of Thermal Expansion (CTE).

According to an aspect of the present invention, there is provided a bonding substrate including: at least one upper substrate; at least one lower substrate which faces and is spaced apart from the upper substrate by a regular distance; and connecting members which comprises at least two layers formed of each different metal and is structurally or electrically ultrasonic bonded to the upper substrate or the lower substrate by using an ultrasonic bonding device.

Here, the upper substrate or the lower substrate may include at least one insulating layer and ceramic layer.

Also, the upper substrate or the lower substrate may include a metal material.

Also, the upper substrate or the lower substrate may include a structure where at least one lower metal layer, an insulating layer, and at least one upper metal layer are stacked.

Also, a thickness of each metal layer included in the connecting members may be 0.01 mm through 3 mm.

Also, at least one metal layer from among the metal layers included in the connecting members may contain 50% or more of any one of Mo and Mn.

Here, a thickness of the metal layer containing any one of Mo and Mn may be 10 μm or above.

Also, most outer metal layers disposed at the upper part and the lower part of the connecting members may each contain 50% or more of Cu.

Also, most outer metal layers disposed at the upper part and the lower part of the connecting members may be formed of the same metal.

Also, the connecting members may include at least one plating layer.

Also, at least one micro gap is formed on an ultrasonic bonded surface disposed between the upper substrate or the lower substrate and the connecting members.

Here, a size of the micro gap may be 0.01 μm through 1 mm.

Also, the ultrasonic bonding device may include a housing for covering a booster to which ultrasonic vibration transmitted from a converter is applied, and a horn including a pocket tool having an engraved hole with a specific structure formed thereon to which the connecting member including one side connected to a front end of the booster and the other side bonded to the substrate is inserted, and the connecting member may be ultrasonic bonded to the substrate while being inserted into the engraved hole.

Here, more than 10% of the total height of the connecting member may be inserted into the engraved hole.

Also, the engraved hole may include at least one penetrating hole and the hole may be a vacuum hole which vacuum adsorbs one surface of the connecting member.

Also, one surface of the connecting member may include knurling pattern marks in correspondence to a knurling pattern formed on the lower surface of the engraved hole.

According to another aspect of the present invention, there is provided a semiconductor package having a double-sided substrate including: at least one upper substrate; at least one lower substrate which faces and is spaced apart from the upper substrate by a regular distance; connecting members which includes at least two layers formed of each different metal and is structurally or electrically ultrasonic bonded to the upper substrate or the lower substrate by using an ultrasonic bonding device; semiconductor chips including one side surface bonded to the upper substrate or the lower substrate by using a first bonding member interposed therebetween and other side surface electrically connected to the connecting member by using a second bonding member interposed therebetween; an electrical connecting member electrically connected between the semiconductor chip and the upper substrate or the lower substrate; a package housing covering the entire semiconductor chips and at least a part of the electrical connecting member; and at least one terminal electrically connected to the upper substrate, the lower substrate, or the upper and lower substrates and exposed to the outside of the package housing.

Here, the upper substrate or the lower substrate may include at least one insulating layer and ceramic layer.

Also, the upper substrate or the lower substrate may include a metal material.

Also, the upper substrate or the lower substrate may include a structure where at least one lower metal layer, an insulating layer, and at least one upper metal layer are stacked.

Also, a thickness of each metal layer included in the connecting members may be 0.01 mm through 3 mm.

Also, at least one metal layer from among the metal layers included in the connecting members may contain 50% or more of any one of Mo and Mn.

Here, a thickness of the metal layer containing any one of Mo and Mn may be 10 μm or above.

Also, most outer metal layers disposed at the upper part and the lower part of the connecting members may each contain 50% or more of Cu.

Also, most outer metal layers disposed at the upper part and the lower part of the connecting members may be formed of the same metal.

Also, the connecting members may include at least one plating layer.

Also, at least one micro gap is formed on an ultrasonic bonded surface disposed between the upper substrate or the lower substrate and the connecting members. Here, a size of the micro gap may be 0.01 μm through 1 mm.

Also, the ultrasonic bonding device may include a housing for covering a booster to which ultrasonic vibration transmitted from a converter is applied, and a horn including a pocket tool having an engraved hole with a specific structure formed thereon to which the connecting member including one side connected to a front end of the booster and the other side bonded to the substrate is inserted, and the connecting member may be ultrasonic bonded to the substrate while being inserted into the engraved hole.

Here, more than 10% of the total height of the connecting member may be inserted into the engraved hole.

Also, the engraved hole may include at least one penetrating hole and the hole may be a vacuum hole which vacuum adsorbs one surface of the connecting member.

Also, one surface of the connecting member may include knurling pattern marks in correspondence to a knurling pattern formed on the lower surface of the engraved hole.

Also, the first bonding member and the second bonding member may contain 50% or more of any one of Ag, Cu, and Sn.

Also, the terminal may be ultrasonic bonded to the upper substrate or the lower substrate.

Also, at least a part of the upper substrate or the lower substrate may be exposed to the surface of the package housing.

Also, the upper substrate or the lower substrate may include at least one radiation fin structurally bonded thereto.

Also, the semiconductor package may be applied to an inverter, a converter, or an On Board Charger (OBC).

According to another aspect of the present invention, there is provided a method of manufacturing a bonding substrate including: preparing at least one upper substrate; preparing at least one lower substrate which faces and is spaced apart from the upper substrate by a regular distance; and structurally or electrically ultrasonic bonding connecting members, which includes at least two layers formed of each different metal, to the upper substrate or the lower substrate by using an ultrasonic bonding device.

Here, the ultrasonic bonding device may include a housing for covering a booster to which ultrasonic vibration transmitted from a converter is applied, and a horn including a pocket tool having an engraved hole with a specific structure formed thereon to which the connecting member including one side connected to a front end of the booster and the other side bonded to the substrate is inserted, and the connecting member may be ultrasonic bonded to the substrate while more than 10% of the total height of the connecting member is inserted into the engraved hole.

Here, the engraved hole may include at least one penetrating hole, the hole may be a vacuum hole which vacuum adsorbs one surface of the connecting member, the connecting member is adsorbed through the vacuum hole, and vacuum may be released after the connecting members are aligned on the lower substrate or the upper substrate.

Also, one surface of the connecting member may include knurling pattern marks in correspondence to a knurling pattern formed on the lower surface of the engraved hole.

According to another aspect of the present invention, there is provided a method of manufacturing a semiconductor package having a double-sided substrate including:

preparing at least one upper substrate; preparing at least one lower substrate which faces and is spaced apart from the upper substrate by a regular distance; structurally or electrically ultrasonic bonding connecting members, which includes at least two layers formed of each different metal, to the upper substrate or the lower substrate by using an ultrasonic bonding device; bonding one side surface of semiconductor chips to the upper substrate or the lower substrate by using a first bonding member interposed therebetween and electrically bonding other side surface of the semiconductor chips to the connecting members by using the second bonding member interposed therebetween; electrically connecting the electrical connecting member between the semiconductor chip and the upper substrate or the lower substrate; forming a package housing to cover the semiconductor chips and at least a part of the electrical connecting member; and electrically connecting at least one terminal to the upper substrate, the lower substrate, or the upper and lower substrates to be exposed to the outside of the package housing.

Here, the ultrasonic bonding device may include a housing for covering a booster to which ultrasonic vibration transmitted from a converter is applied, and a horn including a pocket tool having an engraved hole with a specific structure formed thereon to which the connecting member including one side connected to a front end of the booster and the other side bonded to the substrate is inserted, and the connecting member may be ultrasonic bonded to the substrate while more than 10% of the total height of the connecting member is inserted into the engraved hole.

Here, the engraved hole may include at least one penetrating hole, the hole may be a vacuum hole which vacuum adsorbs one surface of the connecting member, the connecting member is adsorbed through the vacuum hole, and vacuum may be released after the connecting members are aligned on the lower substrate or the upper substrate.

Also, one surface of the connecting member may include knurling pattern marks in correspondence to a knurling pattern formed on the lower surface of the engraved hole.

### BRIEF DESCRIPTION OF THE DRAWINGS

The above and other features and advantages of the present invention will become more apparent by describing in detail exemplary embodiments thereof with reference to the attached drawings in which:

FIGS. 1A and 1B are a cross-sectional view of a semiconductor package having a double-sided substrate which is a bonding substrate according to a conventional art;

FIGS. 2A through 2C are illustrates a bonding structure of a bonding substrate according to a first embodiment of the present invention;

FIGS. 3A and 3B illustrate a micro gap of an ultrasonic bonded surface of FIGS. 2A through 2C;

FIGS. 4A through 4C illustrate a knurling pattern of a connecting member of FIGS. 2A through 2C;

FIGS. 5A and 5B illustrate an ultrasonic bonding device of FIGS. 2A through 2C;

FIGS. 6A through 6F illustrate a process of ultrasonic bonding executed by the ultrasonic bonding device of FIGS. 5A and 5B;

FIGS. 7A through 7D illustrate various examples of a horn included in the ultrasonic bonding device of FIGS. 5A and 5B;

FIGS. 8A through 8F illustrate various examples of engraved holes and knurling patterns of the horn shown in FIGS. 7A through 7D;

FIGS. 9A and 9B illustrate a vacuum hole included in the engraved hole of the horn shown in FIGS. 8A through 8F;

FIGS. 10A and 10B respectively illustrate an exploded view of the ultrasonic bonding device of FIGS. 5A and 5B and a function of a sagging prevention block;

FIGS. 11A and 11B illustrate simulation for setting a nodal point performed by the horn of the ultrasonic bonding device of FIGS. 5A and 5B;

FIGS. 12 through 16 illustrate first through fourth examples of a semiconductor package having a double-sided substrate according to a second embodiment of the present invention;

FIG. 17 illustrates a radiation fin structure of the semiconductor package having a double-sided substrate according to the second embodiment of the present invention;

FIG. 18 is a flowchart schematically illustrating a method of manufacturing a bonding substrate according to a third embodiment of the present invention; and

FIG. 19 is a flowchart schematically illustrating a method of manufacturing a semiconductor package having a double-sided substrate according to a fourth embodiment of the present invention.

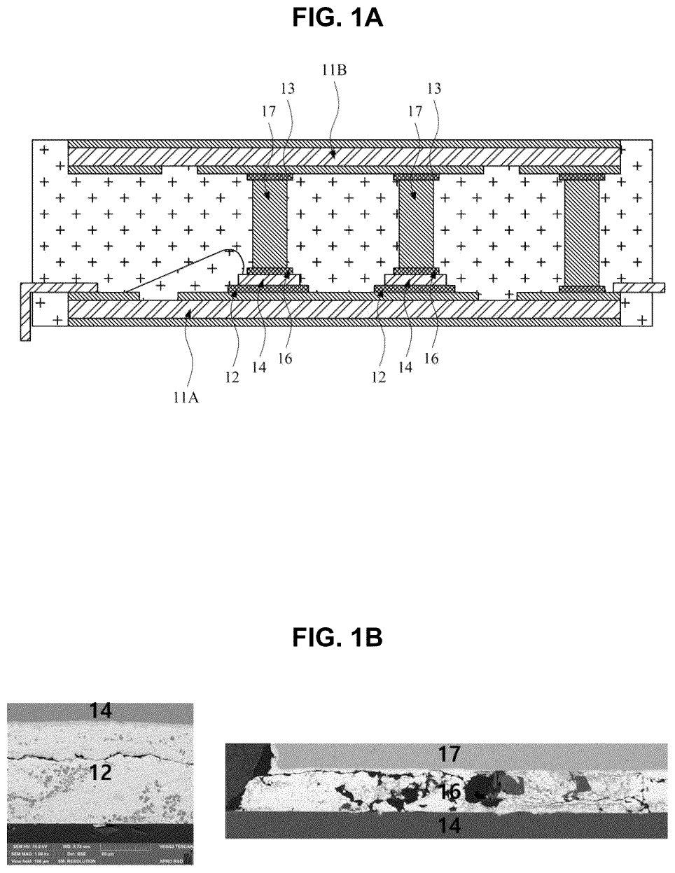

### DETAILED DESCRIPTION OF THE INVENTION

Hereinafter, embodiments of the present invention will be described in more detail with reference to the accompanying drawings.

A bonding substrate according to a first embodiment of the present invention includes at least one upper substrate 100, at least one lower substrate 200, and connecting members 300, wherein the at least one lower substrate 200 faces and is spaced apart from the at least one upper substrate 100 by a regular distance and the connecting members 300 including at least two layers formed of each different metal are structurally or electrically ultrasonic bonded to the upper substrate 100 or the lower substrate 200 by using an ultrasonic bonding device. Accordingly, a tolerance for a vertically separated distance between the upper and lower substrates may be minimized through ultrasonic bonding between the substrate and connecting members and structural stress may be reduced by using connecting members having each different Coefficient of Thermal Expansion (CTE).

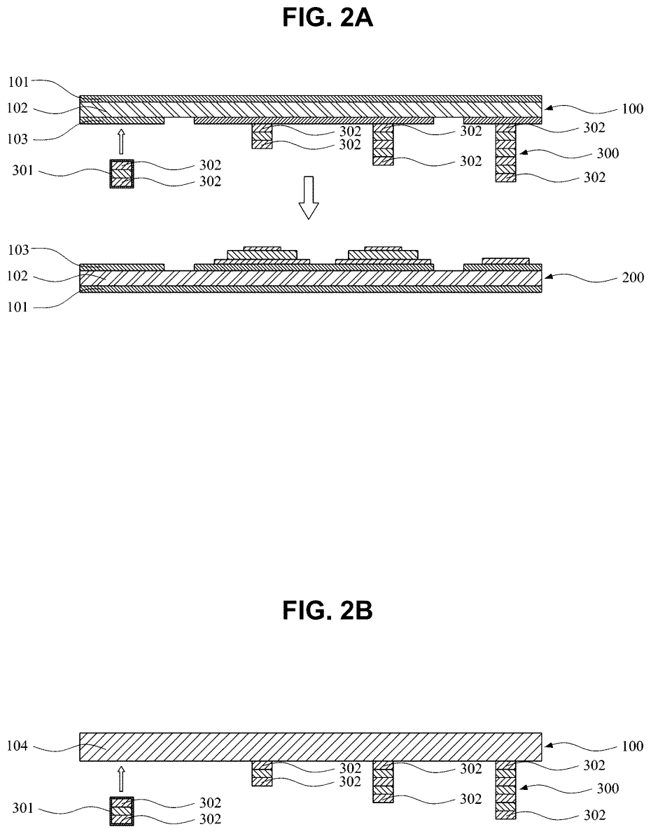

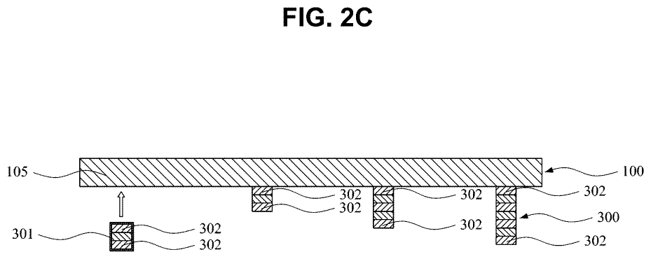

Hereinafter, the bonding substrate as above will be described in more detail below with reference to FIGS. 2A through 11B.

First, the at least one upper substrate 100 may have a structure where at least one lower metal layer 101 which is partially exposed to the outside of a package housing 600, an insulating layer 102, and at least one upper metal layer 103 ultrasonic bonded to the connecting members 300 are stacked in order as illustrated in FIG. 2A, may include at least one insulating layer 104 or at least one ceramic layer 104 formed of Al₂O₃, AlN, or Si₃N₄ as illustrated in FIG. 2B, or may be formed of a metal material 105 as illustrated in FIG. 2C.

Next, the at least one lower substrate 200 faces and is spaced apart from the upper substrate 100 by a regular distance. As illustrated in FIG. 2A, the at least one lower substrate 200 may have a structure where the at least one lower metal layer 101 which is partially exposed to the outside of the package housing 600, the insulating layer 102, and the at least one upper metal layer 103 ultrasonic bonded to the connecting members 300 are stacked in order. Also, in the same manner as the upper substrate 100, the at least one lower substrate 200 may include at least one insulating layer or at least one ceramic layer formed of Al₂O₃, AlN, or Si₃N₄ or may be formed of a metal material.

Next, the connecting members 300 include at least two layers formed of each different metal having each different CTE and are structurally or electrically ultrasonic bonded to the upper substrate 100 and/or the lower substrate 200 by using an ultrasonic bonding device.

In this regard, when in ultrasonic bonding, structural stress of a semiconductor package may be lowered by each different CTE of each layer and the connecting members 300 functioning as metal spacers are ultrasonic bonded to the upper substrate 100 or the lower substrate 200 in advance so as to improve a bonding structure of semiconductor chips 400 and the lower substrate 200 or the upper substrate 100 and a bonding structure of the semiconductor chips 400 and the connecting members 300. Accordingly, a tolerance for a vertically separated distance between the upper substrate 100 and the lower substrate 200 may be minimized.

Here, a thickness of each metal layer included in the connecting members 300 may be 0.01 mm through 3 mm and at least one metal layer from among the metal layers included in the connecting members 300 may contain 50% or more of Mo and/or Mn.

Also, a thickness of the metal layer containing Mo and/or Mn may be at least 10 μm or above.

Meanwhile, referring to FIGS. 2A through 2C, the connecting members 300 may include at least one plating layer 301 to cover inner metal layers.

Here, except for the plating layer 301, most outer metal layers 302 disposed at the upper part and the lower part of the connecting members 300 each contain 50% or more of Cu so that bonding strength and bonding reliability of ultrasonic bonded surfaces may be increased.

Also, except for the plating layer 301, the most outer metal layers 302 disposed at the upper part and the lower part of the connecting members 300 are formed of the same metal so that bonding strength and bonding reliability of ultrasonic bonded surfaces may be increased.

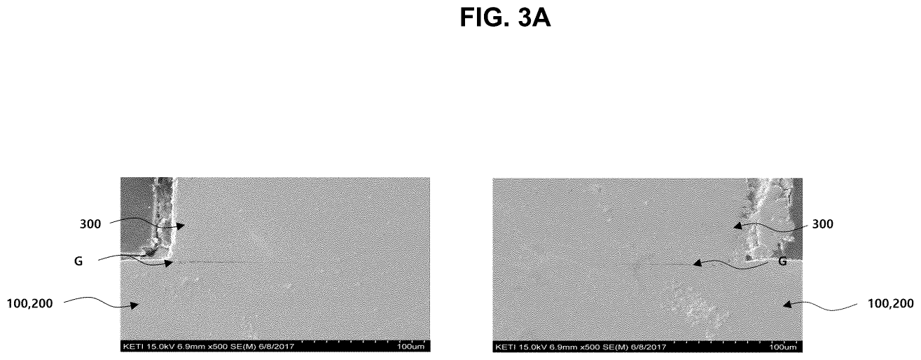

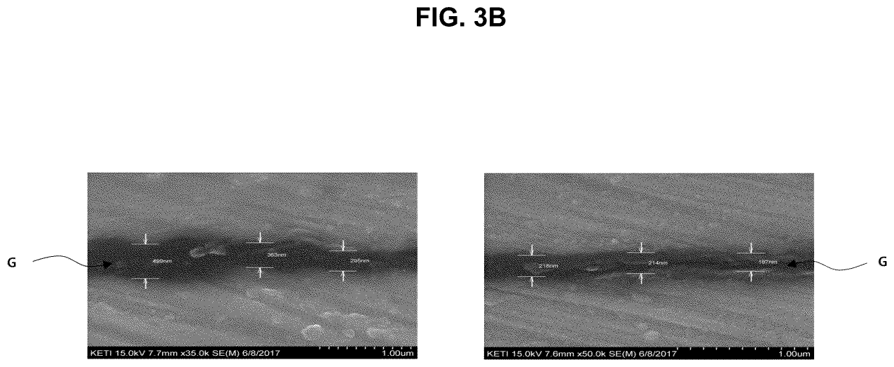

Also, referring to FIGS. 3A and 3B, at least one micro gap G may be formed on an ultrasonic bonded surface disposed between the upper substrate 100 and/or the lower substrate 200 and the connecting members 300 and a size of the micro gap G may be 0.01 μm through 1 mm.

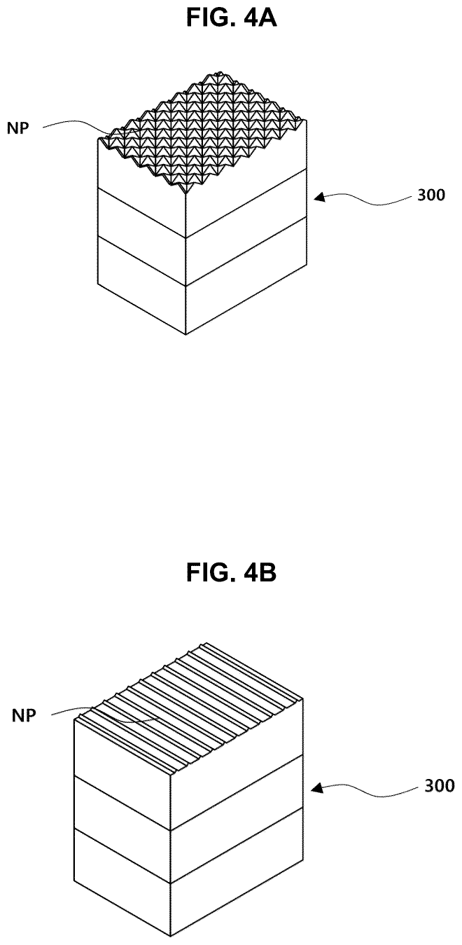

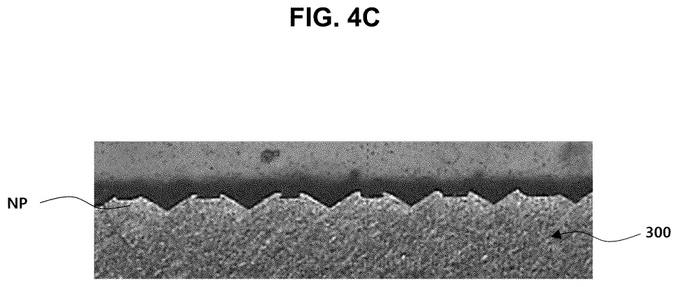

Also, referring to FIGS. 4A through 4C, one surface of the connecting member 300 includes a pocket tool of an ultrasonic bonding device, more preferably, concave or convex knurling pattern marks NP formed by being pressurized from a knurling pattern 126 formed on a bottom surface of an engraved hole 121, so that a surface area may be expanded while spreading a bonding member onto one surface of the connecting member 300 and thereby, bonding strength may be increased.

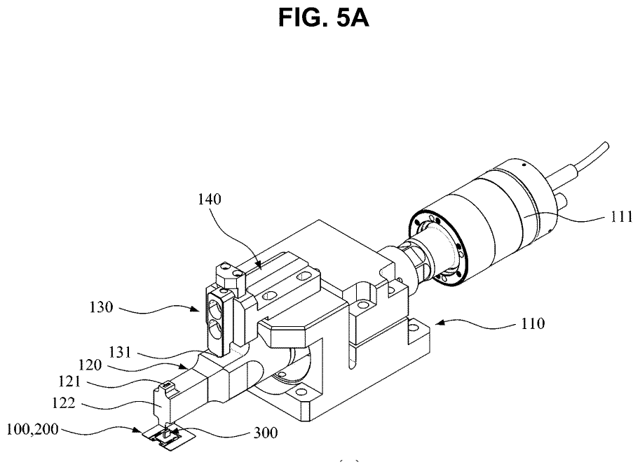

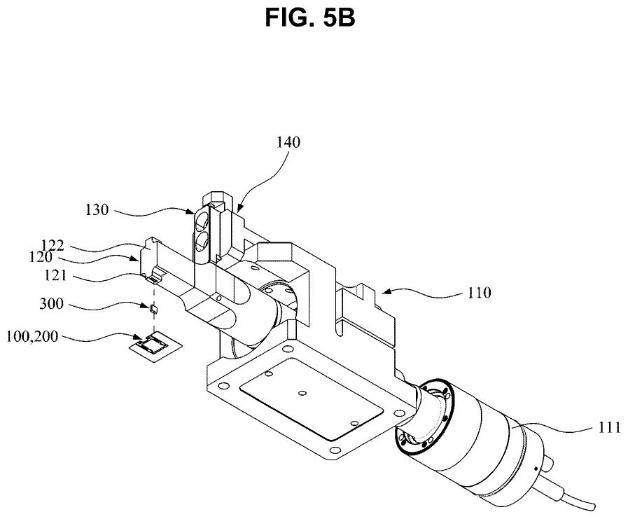

Meanwhile, referring to FIGS. 5A, 5B, 6A through 6F, and 10A, 10B the connecting members 300 are bonded to the upper substrate 100 or the lower substrate 200 by using the ultrasonic bonding device. More specifically, the ultrasonic bonding device includes a housing 110 and a horn 120, wherein the housing 110 covers a booster 112 to which ultrasonic vibration transmitted from a converter 111 is applied, and the horn 120 includes a pocket tool 122 where the engraved hole 121 having a specific structure is formed. Here, the connecting member 300 including one side connected to a front end of the booster 112 and the other side bonded to the upper substrate 100 or the lower substrate 200 is inserted into the engraved hole 121. At least one hole 123 penetrates the engraved hole 121 and ultrasonic waves is transmitted while more than 10% of the total height H of the connecting member 300 is inserted into the engraved hole 121, when the connecting member 300 is ultrasonic bonded to the upper substrate 100 or the lower substrate 200. Accordingly, the connecting member 300 may be stably inserted so that ultrasonic oscillation may be efficiently transmitted.

Here, the housing 110 covers the booster 112 and more specifically, the booster 112 to which ultrasonic vibration transmitted from the converter 111 generating longitudinal vibration of 20 Khz through 35 Khz is applied so that the booster 112 may be combined to a hollow 113 to be fixed.

Meanwhile, a pneumatic cylinder (not illustrated) is combined to the lower surface of the housing 110 to be up and down and the converter 111 converts an electrical signal having high frequency into mechanical longitudinal vibration and is bolt joined to the booster 112 by using a booster bolt 114. The booster 112 outputs amplitude of ultrasonic vibration, which passes between the converter 111 and the horn 120, to the horn 120 by 1:1, raises amplitude, or lowers amplitude.

The horn 120 is combined to the booster 112 to transmit ultrasonic vibration having frequency of 10 Khz through 50 Khz to the connecting members 300. More specifically, one side of the horn 120 is bolt joined to the front end of the booster 112 through a horn bolt 124 and the other side of the horn 120 includes the pocket tool 122 including the engraved hole 121 having a specific structure to which the connecting members 300 bonded to the upper substrate 100 or the upper surface of the lower substrate 200 in the lead frame.

That is, the horn 120 inserts and fixes the connecting member 300 to the engraved hole 121 and transmits the ultrasonic waves to the connecting member 300 so that the connecting member 300 may be ultrasonic bonded to the upper substrate 100 or the lower substrate 200.

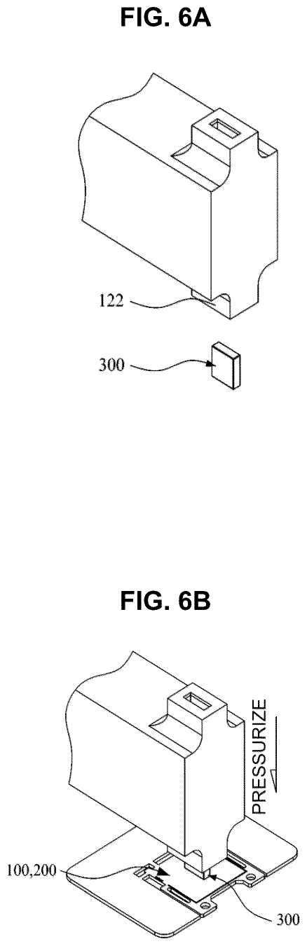

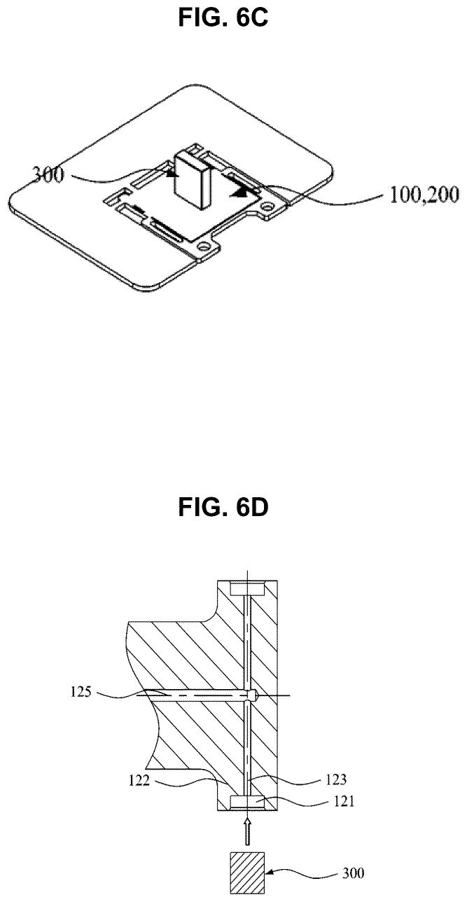

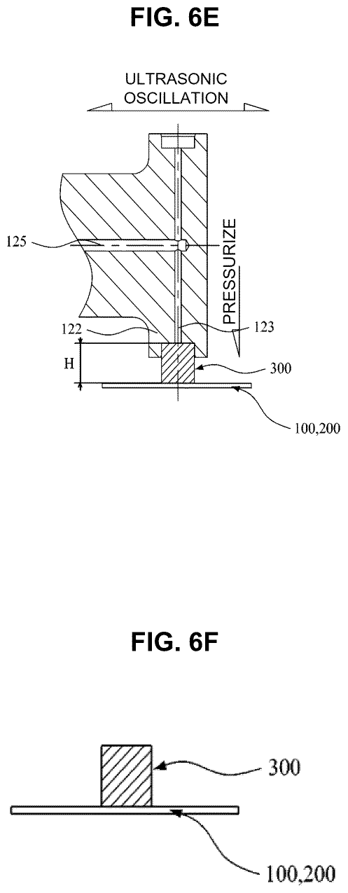

Meanwhile, as illustrated in FIGS. 6D through 6F, at least one hole 123 penetrates the engraved hole 121 and ultrasonic waves is transmitted while more than 10% of the total height H of the connecting member 300 is inserted into the engraved hole 121, when the connecting member 300 is ultrasonic bonded to the upper substrate 100 or the lower substrate 200. Accordingly, the connecting member 300 may be stably inserted and combined to the engraved hole 121.

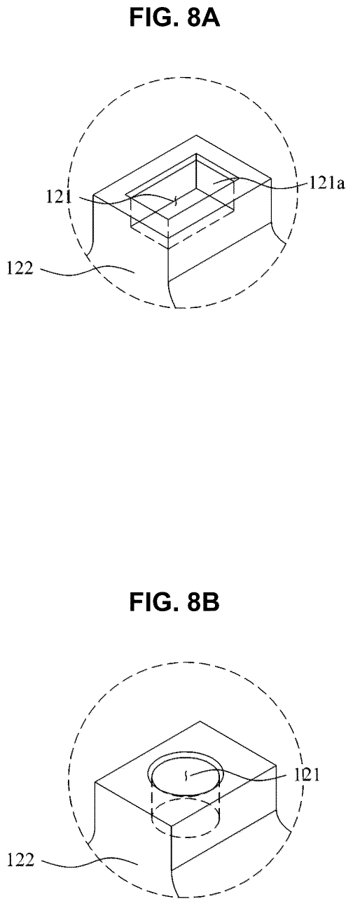

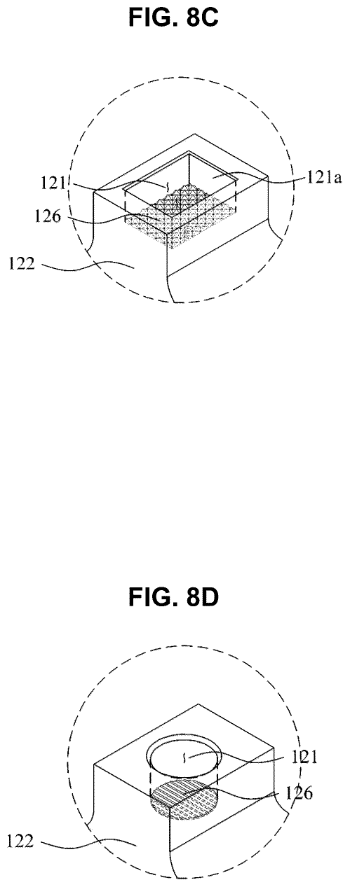

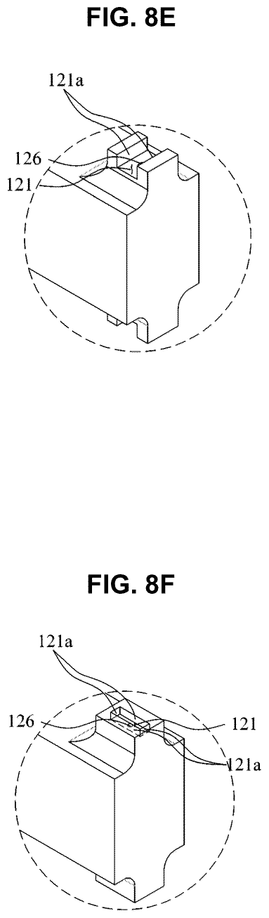

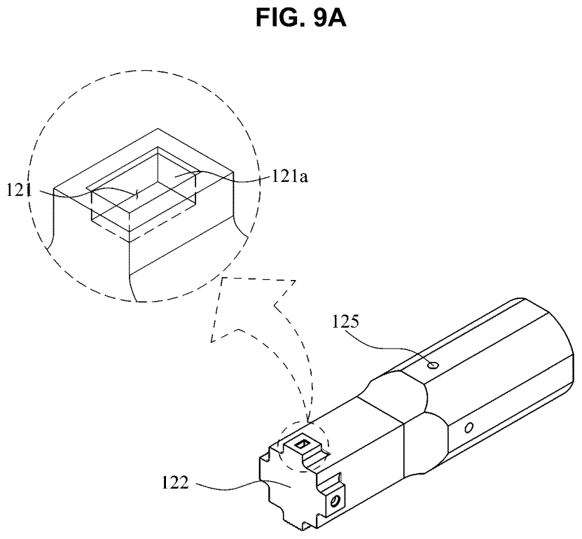

Also, as illustrated in FIG. 8A, the engraved hole 121 may be depressed in a hexahedral shape in correspondence to the shape of the connecting member 300 or as illustrated in FIG. 8B, the engraved hole 121 may be depressed in a cylindrical shape. In this regard, the engraved hole 121 may be formed in various shapes according to adsorptive power required to the connecting member 300 and the shape of the connecting member 300.

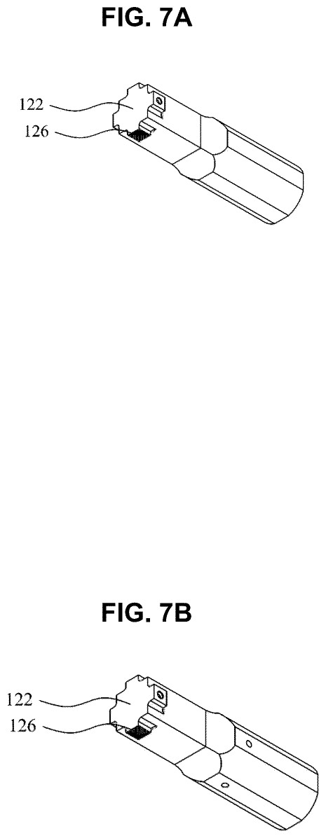

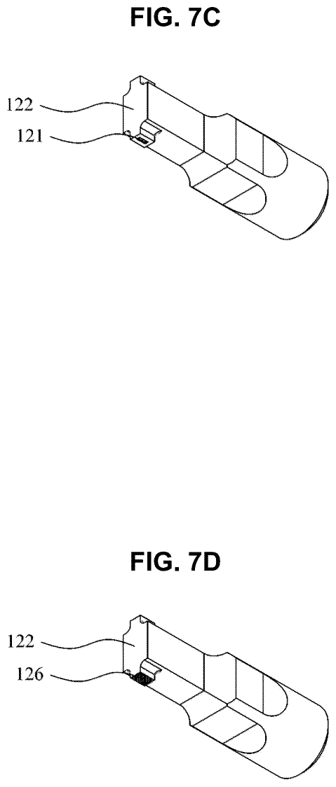

In addition, referring to FIGS. 6A through 6F and 7A through 7D, the hole 123 described above may be a vacuum hole 123 which penetrates the engraved hole 121 and vacuum adsorbs one surface of the connecting member 300 by negative pressure. The connecting member 300 may be adsorbed through the vacuum hole 123 communicated with a vacuum port 125 forming vacuum and vacuum may be released while the connecting member 300 is on the upper substrate 100 or the lower substrate 200.

Then, when the connecting member 300 is ultrasonic bonded to the upper substrate 100 or the lower substrate 200, the pocket tool 122 may pressurize the connecting member 300 for ultrasonic bonding.

Here, while ultrasonic bonding, antioxidative gas may be supplied through the hole 123 to prevent oxidation of the connecting member 300.

Here, the antioxidative gas may be N₂ or gas mixture including N₂. However, the present invention is not limited thereto and the antioxidative gas may include various kinds of gas used to prevent oxidation. Also, means of supplying antioxidative gas may be separately included and more preferably, may be the hole 123.

Also, referring to FIGS. 8C and 8D, the lower surface of the engraved hole 121 may include the knurling pattern 126 so that the knurling pattern 126 is pressurized onto the connecting member 300 and thereby, the knurling pattern marks NP is formed on one surface of the connecting member 300. Also, ultrasonic vibration may be transmitted at the least loss and slip between the connecting member 300 and the horn 120 may be prevented. As illustrated in FIG. 8C, the knurling pattern 126 may be X-type knurling pattern formed variously in the pitch range of 0.3 mm through 1.0 mm or as illustrated in FIG. 8D, the knurling pattern 126 may be a straight-line type knurling pattern formed variously in the pitch range of 0.3 mm through 1.0 mm.

That is, the connecting member 300 is picked by the engraved hole 121 to be placed on the upper substrate 100 or the lower substrate 200 and is vibrated so that the lower surface thereof is ultrasonic bonded to the upper substrate 100 or the lower substrate 200. Also, one surface of the connecting member 300 includes the knurling pattern marks NP in correspondence to the knurling pattern 126 of the engraved hole 121. When other member is bonded to one surface of the connecting member 300 ultrasonic bonded to the upper substrate 100 or the lower substrate 200 by coating an adhesive, a coated area may be widened by the knurling pattern marks NP.

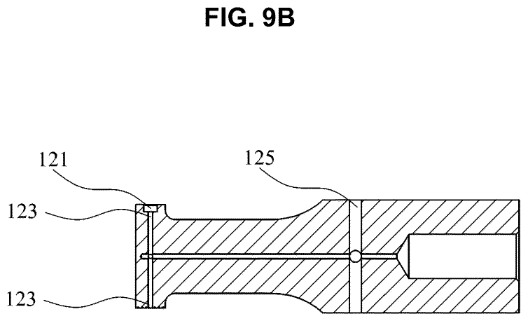

Also, the engraved hole 121 is formed and depressed in a hexahedral shape and as illustrated in FIG. 8E, the engraved hole 121 includes two facing pocket walls 121A to fix and hold the connecting member 300 so as not to be separated therefrom while in ultrasonic vibrations in a longitudinal direction. In addition, as illustrated in FIGS. 8F and 9A, the engraved hole 121 includes four pocket walls 121A facing each other so as to stably vacuum adsorb and fix the connecting member 300.

Also, a material forming the pocket tool 122 may include 50% or more of Fe from among the entire forming material.

In addition, a material forming the pocket tool 122 may include alloy steel containing 2% through 10% of Cr, W and/or Mo.

Also, referring to FIGS. 7A through 7D, in consideration of the durability of the horn 120, the pocket tool 122 is designed to have two-way or four-way end portions used to pressurize the connecting member 300 and thereby, a number of welding areas increases. Accordingly, when the engraved hole 121 is damaged or when the knurling pattern 126 is worn down, other portion of the engraved hole 121 or the knurling pattern 126 may be used.

Meanwhile, a sagging prevention block 130 prevents the horn 120 from being sagged due to ultrasonic vibration and is combined to the upper front part of the housing 110 to press and support a specific point at the upper part of the horn 120, that is, a nodal point. Accordingly, the horn 120 may be prevented from being bent in an upper direction.

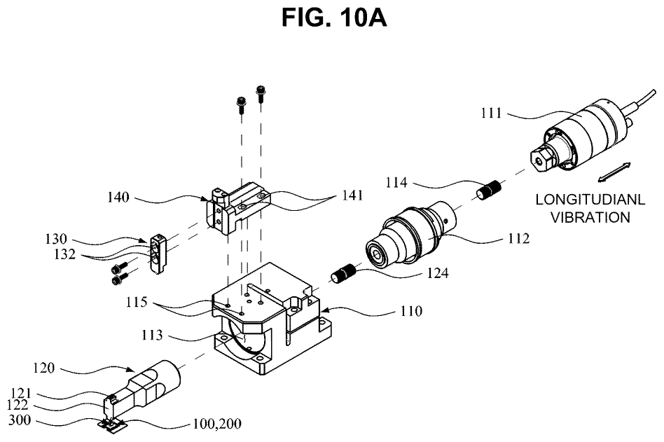

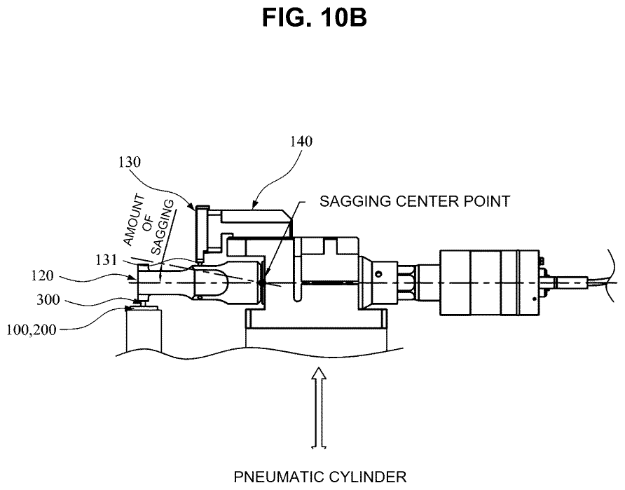

For example, referring to FIG. 10B, when in ultrasonic bonding, the horn 120 is pressurized to a downward direction to apply constant pressure to the connecting member 300. Here, the front end of the horn 120 is deformed by a constant amount of sagging in an upward direction based on a sagging center point C formed on an area where the booster 112 and the horn 120 are connected. Accordingly, the flat connecting member 300 may incline and thus, the entire surface may not be uniformly bonded so that ultrasonic welding may not be appropriately performed. In this regard, a pressure hole 131 having a hemispherical form included in the sagging prevention block 130 may support a nodal point and thereby, the horn 120 may be prevented from being sagged.

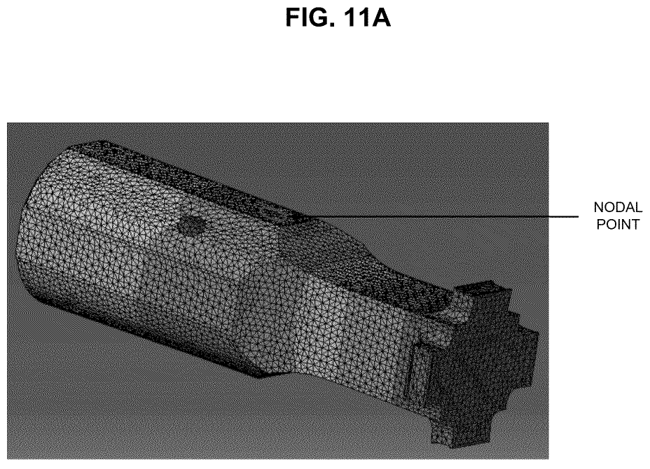

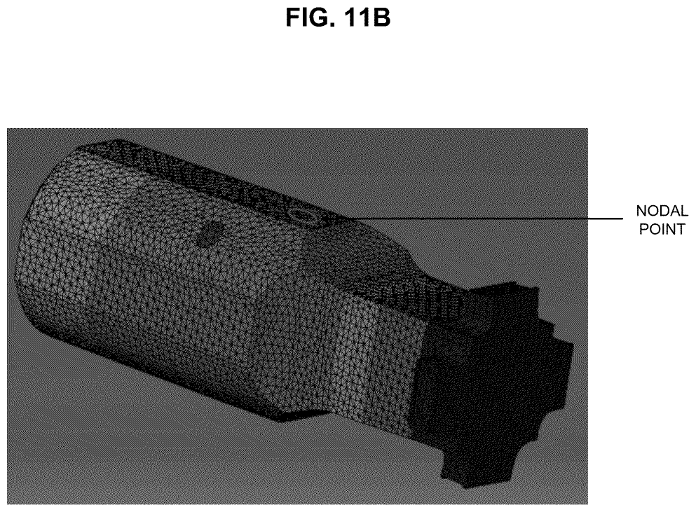

Here, referring to FIGS. 11A and 11B, a nodal point is a resonance point and may be set to a point where ultrasonic oscillation reaches at the least through a simulation. That is, an area where an amplitude starting point with the minimum left and right amplitude occurring due to longitudinal vibration and an amplitude starting point with the maximum left and right amplitude due to longitudinal vibration are overlapped may be set as the nodal point.

For example, the pressure hole 131 of the sagging prevention block 130 may be spaced apart from the center of the engraved hole 121 within the range of 20% through 80% of the total length of the horn 120 to press and support the upper part of the horn 120.

Also, referring to FIGS. 5A, 5B and 10A, 10B, the sagging prevention block 130 includes fastening holes 132 which are long and spaced apart from each other upward and downward. The fastening holes 132 are bolt connected to the front end of a position adjustment block 140 so that up and down position of the sagging prevention block 130 may be adjusted and fixed.

The position adjustment block 140 is combined to the upper part of the housing 110 and may adjust front and rear position of the sagging prevention block 130.

For example, referring to FIG. 10A, bolt holes 115 penetrate and are formed on the upper part of the housing 110 and long fastening holes 141 penetrate and are formed on the position adjustment block 140 in correspondence to the bolt holes 115 so that the bolt holes 115 and the fastening holes 141 are bolt connected and combined to each other. Also, front and rear position of the position adjustment block 140 may be adjusted and thereby, a pressurizing position of the pressure hole 131 may be adjusted.

Meanwhile, the position adjustment block 140 is combined to the upper part of the housing 110 and then, the sagging prevention block 130 may be combined to the front end of the position adjustment block 140.

Here, before the sagging prevention block 130 is combined to the position adjustment block 140, the nodal point of the horn 120 is identified with the naked eye and the sagging prevention block 130 may be pressed with constant pressure by using a coil spring (not illustrated) to accurately set an alignment position until the sagging prevention block 130 is fixed. Then, the sagging prevention block 130 may be fixed to the position adjustment block 140 by using bolts.

In this regard, a power semiconductor such as an Insulated Gate Bipolar Transistor (IGBT), a Metal-Oxide-Semiconductor Field-Effect Transistor (MOSFET), or a diode may be electrically bonded to the connecting member 300, wherein the connecting member 300 ultrasonic bonded to the upper substrate 100 and/or the lower substrate 200 may be formed of a material for forming a semiconductor package.

A semiconductor package having a double-sided substrate according to a second embodiment of the present invention includes at least one upper substrate 100, at least one lower substrate 200, the connecting members 300, the semiconductor chips 400, an electrical connecting member 500, the package housing 600, and at least one terminal 700, wherein the at least one lower substrate 200 faces and is spaced apart from the at least one upper substrate 100 by a regular distance, the connecting members 300 including at least two layers formed of each different metal are structurally or electrically ultrasonic bonded to the upper substrate 100 or the lower substrate 200 by using an ultrasonic bonding device, the semiconductor chips 400 includes one side surface bonded to the upper substrate 100 or the lower substrate 200 by using a first bonding member 401 interposed therebetween and other side surface electrically connected to the connecting member 300 by using a second bonding member 402 interposed therebetween, the electrical connecting member 500 is electrically connected between the semiconductor chip 400 and the upper substrate 100 or the lower substrate 200, the package housing 600 entirely covers the semiconductor chips 400 and covers at least a part of the electrical connecting member 500, and the at least one terminal 700 is electrically connected to the upper substrate 100, the lower substrate 200, or the upper and lower substrates 100 and 200 and is exposed to the outside of the package housing 600. Accordingly, a tolerance for a vertically separated distance between the upper and lower substrates may be minimized through ultrasonic bonding between the substrate and connecting members and structural stress occurring during molding may be reduced by using connecting members having each different CTE.

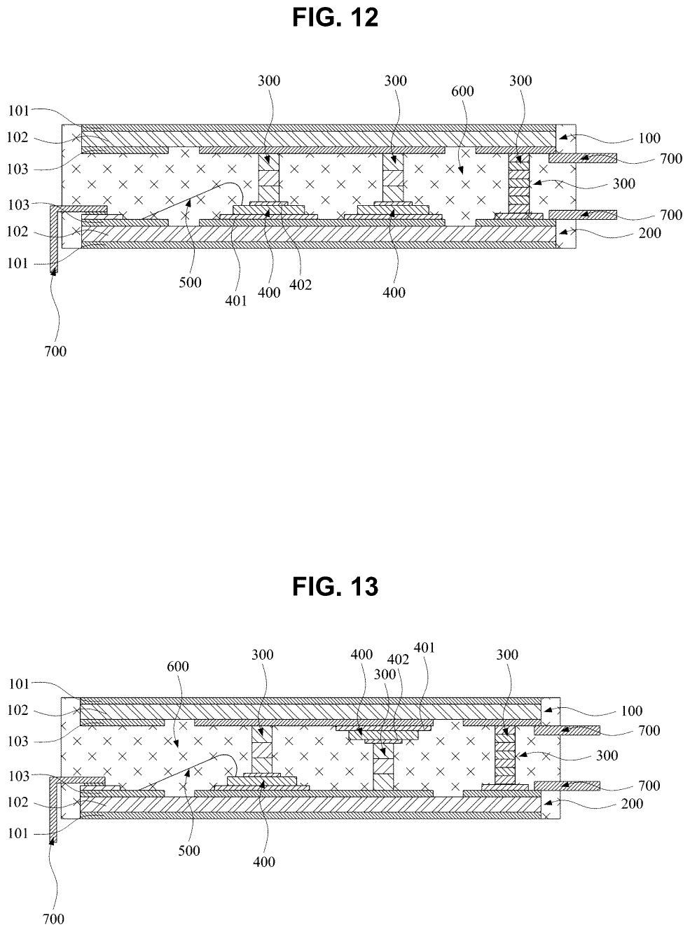

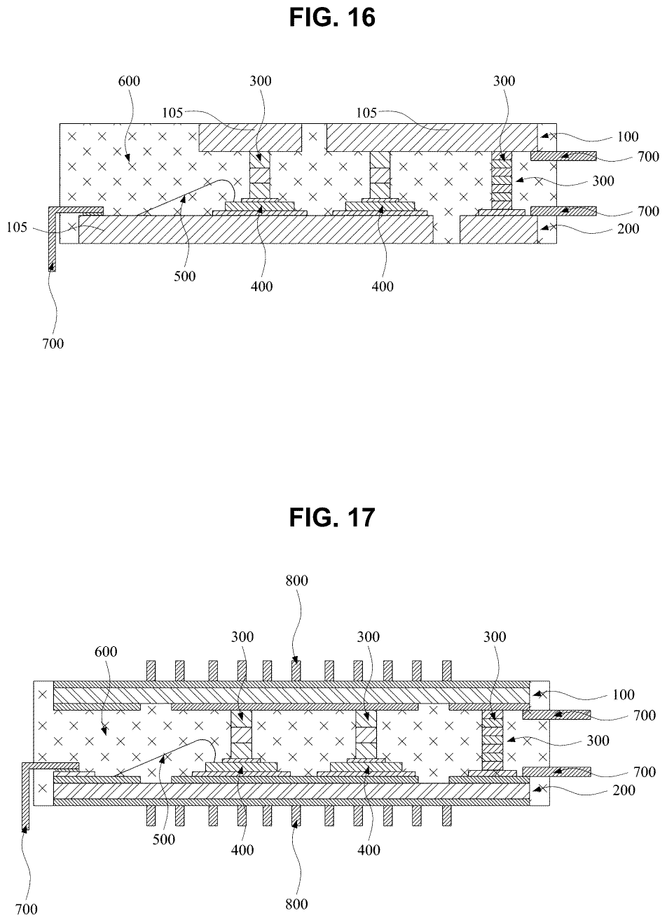

Hereinafter, the semiconductor package having a double-sided substrate as above will be described in more detail below with reference to FIGS. 12 through 17.

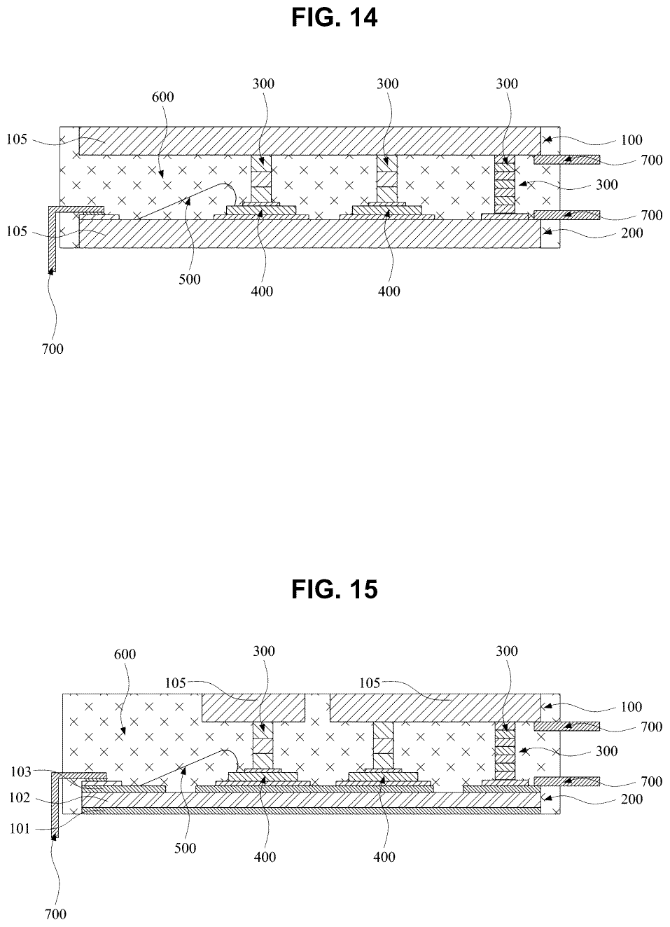

First, the at least one upper substrate 100 may have a structure where at least one lower metal layer 101 which is partially exposed to the outside of the package housing 600, the insulating layer 102, and at least one upper metal layer 103 ultrasonic bonded to the connecting members 300 are stacked in order as illustrated in FIGS. 12 and 13, may include at least one insulating layer or at least one ceramic layer formed of Al₂O₃, AlN, or Si₃N₄, or may be a metal substrate formed of a metal material 105 as illustrated in FIGS. 14 through 16.

Next, the at least one lower substrate 200 faces and is spaced apart from the upper substrate 100 by a regular distance. As illustrated in FIGS. 12 and 13, the at least one lower substrate 200 may have a structure where the at least one lower metal layer 101 which is partially exposed to the outside of the package housing 600, the insulating layer 102, and the at least one upper metal layer 103 ultrasonic bonded to the connecting members 300 are stacked in order. Also, in the same manner as the upper substrate 100, the at least one lower substrate 200 may include at least one insulating layer or at least one ceramic layer formed of Al₂O₃, AlN, or Si₃N₄, or may be a metal substrate formed of the metal material 105.

Next, the connecting members 300 include at least two layers formed of each different metal having each different CTE and are structurally or electrically ultrasonic bonded to the upper substrate 100 and/or the lower substrate 200 by using the ultrasonic bonding device.

In this regard, when in ultrasonic bonding, structural stress of a semiconductor package may be lowered by each different CTE of each layer and the connecting members 300 functioning as metal spacers are ultrasonic bonded to the upper substrate 100 or the lower substrate 200 in advance so as to improve a bonding structure of the semiconductor chips 400 and the lower substrate 200 or the upper substrate 100 and a bonding structure of the semiconductor chips 400 and the connecting members 300. Accordingly, a tolerance for a vertically separated distance between the upper substrate 100 and the lower substrate 200 may be minimized.

Here, a thickness of each metal layer included in the connecting members 300 may be 0.01 mm through 3 mm and at least one metal layer from among the metal layers included in the connecting members 300 may contain 50% or more of Mo and/or Mn.

Also, a thickness of the metal layer containing Mo and/or Mn may be at least 10 μm or above.

Meanwhile, referring to FIGS. 2A through 2C, the connecting members 300 may include at least one plating layer 301 to cover inner metal layers.

Here, except for the plating layer 301, the most outer metal layers 302 disposed at the upper part and the lower part of the connecting members 300 each contain 50% or more of Cu so that bonding strength and bonding reliability of ultrasonic bonded surfaces may be increased.

Also, except for the plating layer 301, the most outer metal layers 302 disposed at the upper part and the lower part of the connecting members 300 are formed of the same metal so that bonding strength and bonding reliability of ultrasonic bonded surfaces may be increased.

Also, referring to FIGS. 3A and 3B, at least one micro gap G may be formed on an ultrasonic bonded surface disposed between the upper substrate 100 and/or the lower substrate 200 and the connecting members 300 and a size of the micro gap G may be 0.01 μm through 1 mm.

Also, referring to FIGS. 4A through 4C, one surface of the connecting member 300 includes a pocket tool of an ultrasonic bonding device, more preferably, concave or convex knurling pattern marks NP formed by being pressurized from the knurling pattern 126 formed on the bottom surface of the engraved hole 121, so that a surface area may be expanded while spreading a bonding member onto one surface of the connecting member 300 and thereby, bonding strength may be increased.

Meanwhile, the ultrasonic bonding device which performs ultrasonic bonding is same as the ultrasonic bonding device applied to the bonding substrate according to the first embodiment and thereby, the detailed description is omitted.

Next, one side surface of the semiconductor chip 400 is bonded to the upper substrate 100 (refer to FIG. 13) or the lower substrate 200 (refer to FIG. 12) by using the first bonding member 401 interposed therebetween and the other side surface of the semiconductor chip 400 is electrically connected to the connecting member 300 by using the second bonding member 402 interposed therebetween.

Here, the first bonding member 401 and the second bonding member 402 may contain 50% or more of any one from among Ag, Cu, and Sn.

Also, the semiconductor chip 400 is an IGBT, a MOSFET, diode, or a Junction Field Effect Transistor (JFET) which is a power semiconductor chip and may be applied to drive a device such as an inverter, a converter, or an On Board Charger (OBC) that converts or controls power by using the power semiconductor chip.

In this regard, such power semiconductor is used in a power conversion device that converts power and thereby, may be applied in a high-power conversion device used to switch and control a motor that converts power from DC to AC in electric vehicles and hybrid electric vehicles.

Next, the electrical connecting member 500 may be a bonding wire or a metal clip which is electrically connected between the semiconductor chip 400 and the upper substrate 100 or the lower substrate 200 to apply an electrical signal.

Next, the package housing 600 is molded to cover the entire semiconductor chips 400 and at least a part of the electrical connecting member 500 and is formed of EMC, PBT, or PPS to insulate the semiconductor chips 400.

Next, the at least one terminal 700 is electrically connected to the upper substrate 100, the lower substrate 200, or the upper and lower substrates 100 and 200 and is extended to be exposed to the outside of the package housing 600.

Also, the terminals 700 may be ultrasonic bonded to the upper substrate 100 and/or the lower substrate 200 by using the ultrasonic bonding device described above.

In addition, referring to FIG. 17, at least a part of the upper substrate 100 or the lower substrate 200 is exposed to the surface of the package housing 600 so as to be radiated and at least one radiation fin 800 is structurally bonded to the upper substrate 100 or the lower substrate 200 so that heat radiation effect may be increased.

For example, a heat sink (not illustrated) may be bonded to the radiation fins 800 so as to circulate a coolant such as refrigerant, cooling oil, or cooling water and thereby, cooling effect may be increased.

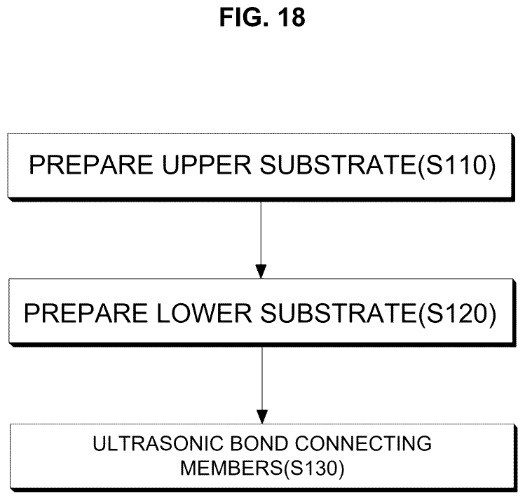

Meanwhile, a method of manufacturing a bonding substrate according to a third embodiment of the present invention will be briefly described below with reference to FIG. 18.

That is, the method of manufacturing the bonding substrate includes preparing at least one upper substrate 100 in operation S110, preparing at least one lower substrate 200, which faces and is spaced apart from the upper substrate 100 by a regular distance, in operation S120, and structurally or electrically ultrasonic bonding the connecting members 300 including at least two layers formed of each different metal to the upper substrate 100 or the lower substrate 200 by using the ultrasonic bonding device in operation S130.

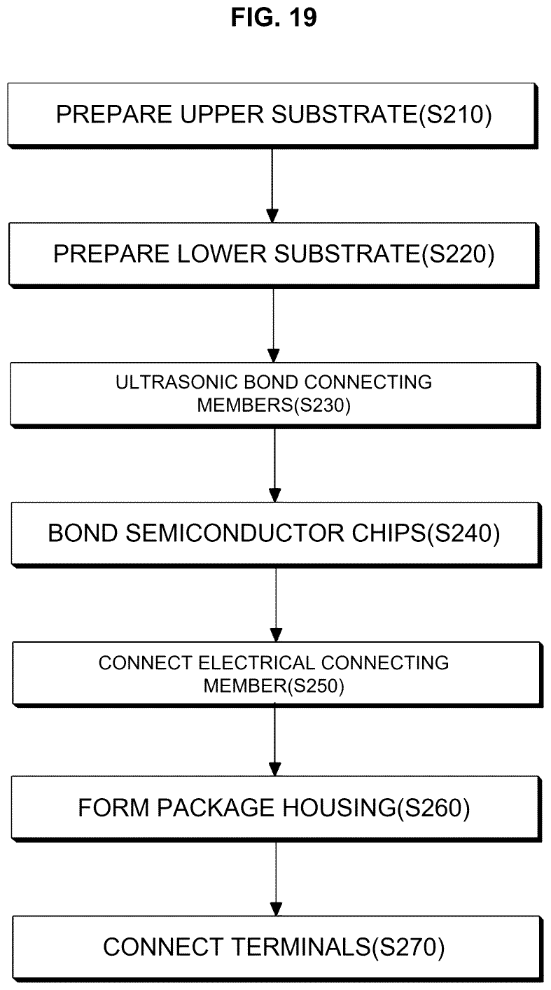

A method of manufacturing a semiconductor package having a double-sided substrate according to a fourth embodiment of the present invention will be briefly described below with reference to FIG. 19.

That is, the method of manufacturing a semiconductor package having a double-sided substrate includes preparing at least one upper substrate 100 in operation S210, preparing at least one lower substrate 200, which faces and is spaced apart from the upper substrate 100 by a regular distance, in operation S220, structurally or electrically ultrasonic bonding the connecting members 300 including at least two layers formed of each different metal to the upper substrate 100 or the lower substrate 200 by using the ultrasonic bonding device in operation S230, bonding one side surface of the semiconductor chips 400 to the upper substrate 100 or the lower substrate 200 by using the first bonding member 401 interposed therebetween and electrically connecting the other side surface of the semiconductor chips 400 to the connecting members 300 by using the second bonding member 402 interposed therebetween in operation S240, electrically connecting the electrical connecting member 500 between the semiconductor chip 400 and the upper substrate 100 or the lower substrate 200 in operation S250, forming the package housing 600 to cover the entire semiconductor chips 400 and at least a part of the electrical connecting member 500 in operation S260, and electrically connecting at least one terminal 700 to the upper substrate 100, the lower substrate 200, or the upper and lower substrates 100 and 200 to be exposed to the outside of the package housing 600 in operation S270.

Here, in the third and fourth embodiments, as in the same manner, referring to FIGS. 5A, 5B, 6A through 6F, and 10A, 10B, the connecting members 300 are bonded to the upper substrate 100 or the lower substrate 200 by using the ultrasonic bonding device. Here, the ultrasonic bonding device includes the housing 110 and the horn 120, wherein the housing 110 covers the booster 112 to which ultrasonic vibration transmitted from the converter 111 is applied, and the horn 120 includes the pocket tool 122 where the engraved hole 121 having a specific structure is formed. Here, the connecting member 300 including one side connected to the front end of the booster 112 and the other side bonded to the upper substrate 100 or the lower substrate 200 is inserted into the engraved hole 121. At least one hole 123 penetrates the engraved hole 121 and ultrasonic waves is transmitted while more than 10% of the total height of the connecting member 300 is inserted into the engraved hole 121, when the connecting member 300 is ultrasonic bonded to the upper substrate 100 or the lower substrate 200. Accordingly, the connecting member 300 may be stably inserted so that ultrasonic oscillation may be efficiently transmitted.

Also, the horn 120 is combined to the booster 112 to transmit ultrasonic vibration having frequency of 10 Khz through 50 Khz to the connecting members 300. More specifically, one side of the horn 120 is bolt joined to the front end of the booster 112 through the horn bolt 124 and the other side of the horn 120 includes the pocket tool 122 including the engraved hole 121 having a specific structure to which the connecting members 300 bonded to the upper substrate 100 or the upper surface of the lower substrate 200 in the lead frame.

That is, the horn 120 inserts and fixes the connecting member 300 to the engraved hole 121 and transmits the ultrasonic waves to the connecting member 300 so that the connecting member 300 may be ultrasonic bonded to the upper substrate 100 or the lower substrate 200.

Meanwhile, as illustrated in FIGS. 6D through 6F, at least one hole 123 penetrates the engraved hole 121 and ultrasonic waves is transmitted while more than 10% of the total height H of the connecting member 300 is inserted into the engraved hole 121, when the connecting member 300 is ultrasonic bonded to the upper substrate 100 or the lower substrate 200. Accordingly, the connecting member 300 may be stably inserted and combined to the engraved hole 121.

In addition, referring to FIGS. 6A through 6F and 7A through 7D, the hole 123 described above may be a vacuum hole 123 which penetrates the engraved hole 121 and vacuum adsorbs one surface of the connecting member 300 by negative pressure. The connecting member 300 may be adsorbed through the vacuum hole 123 communicated with the vacuum port 125 forming vacuum and vacuum may be released while the connecting member 300 is aligned on the upper substrate 100 or the lower substrate 200.

Then, when the connecting member 300 is ultrasonic bonded to the upper substrate 100 or the lower substrate 200, the pocket tool 122 may pressurize the connecting member 300 for ultrasonic bonding.

Also, referring to FIGS. 8C and 8D, the lower surface of the engraved hole 121 may include the knurling pattern 126 so that the knurling pattern 126 is pressurized onto the connecting member 300 and thereby, the knurling pattern marks NP is formed on one surface of the connecting member 300. Also, ultrasonic vibration may be transmitted at the least loss and slip between the connecting member 300 and the horn 120 may be prevented. As illustrated in FIG. 8C, the knurling pattern 126 may be X-type knurling pattern formed variously in the pitch range of 0.3 mm through 1.0 mm or as illustrated in FIG. 8D, the knurling pattern 126 may be a straight-line type knurling pattern formed variously in the pitch range of 0.3 mm through 1.0 mm.

That is, the connecting member 300 is picked by the engraved hole 121 to be placed on the upper substrate 100 or the lower substrate 200 and is vibrated so that the lower surface of the connecting member 300 is ultrasonic bonded to the upper substrate 100 or the lower substrate 200. Also, one surface of the connecting member 300 includes the knurling pattern marks NP in correspondence to the knurling pattern 126 of the engraved hole 121. When other member is bonded to one surface of the connecting member 300 ultrasonic bonded to the upper substrate 100 or the lower substrate 200 by coating an adhesive, a coated area may be widened by the knurling pattern marks NP.

Also, the engraved hole 121 is formed and depressed in a hexahedral shape and as illustrated in FIG. 8E, the engraved hole 121 includes two facing pocket walls 121A to fix and hold the connecting member 300 so as not to be separated therefrom while in ultrasonic vibrations in a longitudinal direction. In addition, as illustrated in FIGS. 8F and 9A, the engraved hole 121 includes four pocket walls 121A facing each other so as to stably vacuum adsorb and fix the connecting member 300.

According to each embodiment of the present invention described above, a tolerance for a vertically separated distance between upper and lower substrates may be minimized through ultrasonic bonding between the substrate and the connecting member, structural stress generated while molding may be reduced by using connecting members having each different CTE, the connecting members may be stably inserted, adsorbed, picked, and placed to be aligned on the substrate, the nodal point of the horn may be supported by the sagging prevention block to prevent the horn from being sagged, and thereby, the connecting members may be uniformly bonded to the substrate.

According to the present invention, a tolerance for a vertically separated distance between upper and lower substrates may be minimized through ultrasonic bonding between the substrate and the connecting member, structural stress generated while molding may be reduced by using connecting members having each different CTE, the connecting members may be stably inserted, adsorbed, picked, and placed to be aligned on the substrate, the nodal point of the horn may be supported by the sagging prevention block to prevent the horn from being sagged, and thereby, the connecting members may be uniformly bonded to the substrate.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A bonding substrate comprising:
at least one upper substrate;
at least one lower substrate which faces and is spaced apart from the upper substrate by a regular distance; and
connecting members which comprises at least two layers formed of each different metal and is structurally or electrically ultrasonic bonded to the upper substrate or the lower substrate by using an ultrasonic bonding device.

2. The bonding substrate of claim 1, wherein the upper substrate or the lower substrate comprises at least one insulating layer, at least one ceramic layer, a metal material, or a structure where at least one lower metal layer, an insulating layer, and at least one upper metal layer are stacked.

3. The bonding substrate of claim 1, wherein a thickness of each metal layer included in the connecting members is 0.01 mm through 3 mm.

4. The bonding substrate of claim 1, wherein at least one metal layer from among the metal layers included in the connecting members contains 50% or more of any one of Mo and Mn.

5. The bonding substrate of claim 4, wherein a thickness of the metal layer containing any one of Mo and Mn is 10 μm or above.

6. The bonding substrate of claim 1, wherein most outer metal layers disposed at the upper part and the lower part of the connecting members each contain 50% or more of Cu.

7. The bonding substrate of claim 1, wherein most outer metal layers disposed at the upper part and the lower part of the connecting members are formed of the same metal.

8. The bonding substrate of claim 1, wherein the connecting members comprise at least one plating layer.

9. The bonding substrate of claim 1, wherein at least one micro gap is formed on an ultrasonic bonded surface disposed between the upper substrate or the lower substrate and the connecting members.

10. The bonding substrate of claim 9, wherein a size of the micro gap is 0.01 μm through 1 mm.

11. The bonding substrate of claim 1, wherein the ultrasonic bonding device comprises a housing for covering a booster to which ultrasonic vibration transmitted from a converter is applied, and a horn comprising a pocket tool having an engraved hole with a specific structure formed thereon to which the connecting member comprising one side connected to a front end of the booster and the other side bonded to the substrate is inserted, and the connecting member is ultrasonic bonded to the substrate while being inserted into the engraved hole.

12. The bonding substrate of claim 11, wherein more than 10% of the total height of the connecting member is inserted into the engraved hole.

13. The bonding substrate of claim 11, wherein the engraved hole comprises at least one penetrating hole and the hole is a vacuum hole which vacuum adsorbs one surface of the connecting member.

14. The bonding substrate of claim 11, wherein one surface of the connecting member comprises knurling pattern marks in correspondence to a knurling pattern formed on the lower surface of the engraved hole.

15. A semiconductor package having a double-sided substrate comprising:
at least one upper substrate;
at least one lower substrate which faces and is spaced apart from the upper substrate by a regular distance;
connecting members which comprises at least two layers formed of each different metal and is structurally or electrically ultrasonic bonded to the upper substrate or the lower substrate by using an ultrasonic bonding device;
semiconductor chips comprising one side surface bonded to the upper substrate or the lower substrate by using a first bonding member interposed therebetween and other side surface electrically connected to the connecting member by using a second bonding member interposed therebetween;
an electrical connecting member electrically connected between the semiconductor chip and the upper substrate or the lower substrate;
a package housing covering the entire semiconductor chips and at least a part of the electrical connecting member; and
at least one terminal electrically connected to the upper substrate, the lower substrate, or the upper and lower substrates and exposed to the outside of the package housing.

16. The semiconductor package of claim 15, wherein the first bonding member and the second bonding member contain 50% or more of any one of Ag, Cu, and Sn.

17. The semiconductor package of claim 15, wherein the terminal is ultrasonic bonded to the upper substrate or the lower substrate.

18. The semiconductor package of claim 15, wherein the upper substrate or the lower substrate comprises at least one radiation fin structurally bonded thereto.

19. A method of manufacturing a bonding substrate comprising:
preparing at least one upper substrate;
preparing at least one lower substrate which faces and is spaced apart from the upper substrate by a regular distance; and
structurally or electrically ultrasonic bonding connecting members, which comprises at least two layers formed of each different metal, to the upper substrate or the lower substrate by using an ultrasonic bonding device.

20. A method of manufacturing a semiconductor package having a double-sided substrate comprising:
preparing at least one upper substrate;
preparing at least one lower substrate which faces and is spaced apart from the upper substrate by a regular distance;
structurally or electrically ultrasonic bonding connecting members, which comprises at least two layers formed of each different metal, to the upper substrate or the lower substrate by using an ultrasonic bonding device;
bonding one side surface of semiconductor chips to the upper substrate or the lower substrate by using a first bonding member interposed therebetween and electrically bonding other side surface of the semiconductor chips to the connecting members by using the second bonding member interposed therebetween;
electrically connecting the electrical connecting member between the semiconductor chip and the upper substrate or the lower substrate;
forming a package housing to cover the semiconductor chips and at least a part of the electrical connecting member; and
electrically connecting at least one terminal to the upper substrate, the lower substrate, or the upper and lower substrates to be exposed to the outside of the package housing.
